(19) United States
(12) Patent Application Publication
(10) Pub. No.: US 2009/0190311 A1
(43) Pub. Date: Jul. 30, 2009

(54) ELECTRONIC ELEMENT PACKAGING

(76) Inventor: Yu-kang Peng, Taipei City (TW)

Correspondence Address: SINORICA, LLC, 2275 Research Blvd., Suite 500, ROCKVILLE, MD, 20850, US

(21) Appl. No.: 12/019,218

(22) Filed: Jan. 24, 2008

(51) Int. Cl. H05K 7/02; G06F 1/16; H05K 7/20

(52) U.S. Cl. 361/704; 361/688; 361/807; 361/811

(57) ABSTRACT

An electronic element packaging is provided, the unit is formed with a colloid layer in a predetermined shape, and a chipset is adhered and mounted inside the colloid layer and comprises a predetermined chip and a conductor so that the unit is packaged without any substrate, thereby the costs of substrate use and design being decreased when the unit is fabricated. No consideration of the difference of heat expansion coefficient of the chip from that of substrate is made, thereby the reliability being increased and the service life being prolonged.

### BACKGROUND OF THE INVENTION

1. Field of the Invention

This invention relates to an element packaging and particularly to a packaging of an electronic element without any substrate.

2. Description of Related Art

With reference to FIG. 1, in a conventional integrated circuit is based on a lead frame 1 as a main body, an adhesive resin 2 is coated on a lead frame 1, a die 3 is connected and fixed onto the lead frame 1, a bonding wire 4 is used to connect the lead frame 1 conductively to the die 3, and finally a resin 5 is used for encapsulation, thereby an integrated circuit being formed. However, in the conventional method of encapsulation, materials are different in the coefficient of heat expansion, and thus the encapsulated component is easily damaged when being heated to cause a stress strain.

Consequently, because of the technical defects of described above, the applicant keeps on carving unflaggingly through wholehearted experience and research to develop the present invention, which can effectively improve the defects described above.

### SUMMARY OF THE INVENTION

In this invention, an electronic element packaging is provided, and the unit mainly comprises a colloid layer in a predetermined form, in which a chipset is adhered and mounted. The chipset comprises the determined chip and the predetermined conductor and could be adhered and mounted without any substrate. The chipset that does not need the substrate could be mounted to the colloid layer, thereby the costs of substrate design and use for increasing the competitive capability. Further, fewer substrate is used, damage of the heated stress strain could be decreased for increasing the yield factor and reliability of the unit.

### BRIEF DESCRIPTION OF THE DRAWINGS

FIG. 1 is a schematic view illustrating the encapsulation of a conventional chip;

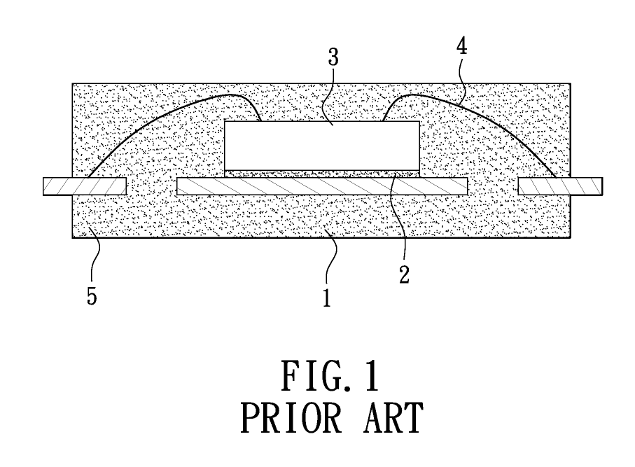

FIG. 2 is a schematic view illustrating the flow of preferred embodiment of this invention;

FIG. 3 is a schematic view illustrating the preferred embodiment of this invention;

FIG. 4 is a schematic view illustrating another embodiment of this invention;

FIG. 5 is a 3D view of the appearance of a further embodiment of this invention;

FIG. 6 is a schematic view illustrating a next embodiment of this invention for connection;

FIG. 7 is a 3D view of the appearance of another embodiment of this invention;

FIG. 8 is a schematic view illustrating a next embodiment of this invention for connection; and

FIG. 9 is a schematic view illustrating a still next embodiment of this invention.

### DETAILED DESCRIPTION OF THE PREFERRED EMBODIMENTS

Now, the present invention will be described more specifically with reference to the following embodiments. It is to be noted that the following descriptions of preferred embodiments of this invention are presented herein for purpose of illustration and description only; it is not intended to be exhaustive or to be limited to the precise form disclosed.

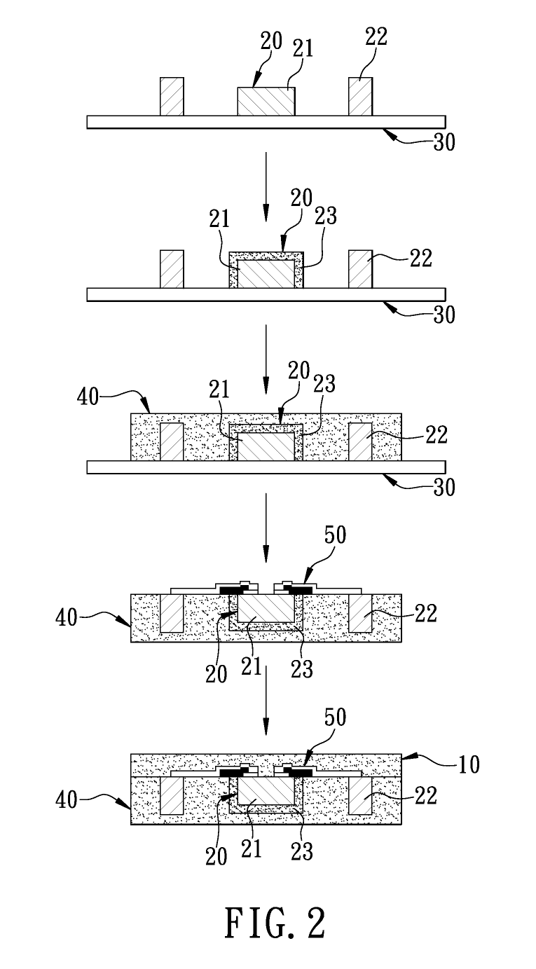

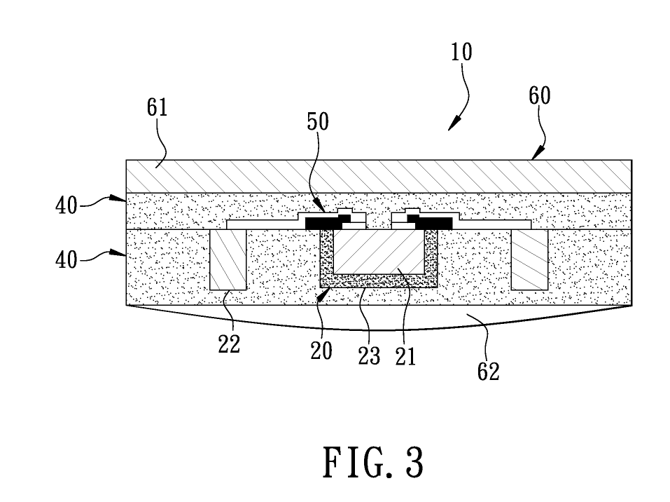

With reference to FIGS. 2 and 3, a preferred embodiment of an electronic element packaging is provided in this invention. Before the unit 10 is formed, a chipset 20 comprising a conductor 22 and a chip 21 without any substrate is mounted onto a carrier 30 removable. In this invention, the chip 21 is a LED element and may be an integrated circuit, a passive component and the like that are necessarily packaged. The chip 21 is spread with a functional glue 23 that is a fluorescent colloid in this invention or another colloid, and then adhered with a colloid layer 40; after the colloid layer 40 solidifies, the carrier 30 is removed. After the carrier 30 is removed, a portion of the chipset 20 that is formed without any colloid layer 40 is connected to the conductor 22 or the chip 21 for electrical conduction by using a conductive part 50, such as a conductive glue or a bonding wire, or the conductor 22 is directly mounted onto the chip 21 for electrical conduction. Next, the portion of the chipset 20, which is not sealed, is adhered and mounted with the colloid layer 40. If the chipset 20 does not need sealing, the step of sealing may also be omitted. Besides, the carrier 30 may be directly formed into a colloid layer that is never removed, and thus the chipset 20 is adhered and mounted after being adhered and mounted onto the carrier 30.

In order to further make apparent the structural features, applied skill and manners, and expected effects according to this invention, what are applied in this invention are in detail described, and it is thus believed that this invention is thoroughly and concretely apparent, as described below.

With reference to FIG. 3, after the unit 10 is sealed, the chip 21 is a LED and become bright when turning ON. The chipset 10 that does not need any substrate may be mounted to the colloid layer 40 so that not only the costs of substrate design and use is saved but the flow of manufacturing the unit 10 is simplified. In the meantime, the chip 21 in the unit 10 may give out light in a complete period. Further, an active layer 60 is formed at the outside of the unit 10 and the active layer 60 according to this invention is structured with a reflecting layer 61 and a diffusion film 62, in which the reflecting layer 61 may reflect a light given by the LED and the light is diffused and emitted by the diffusion film 62.

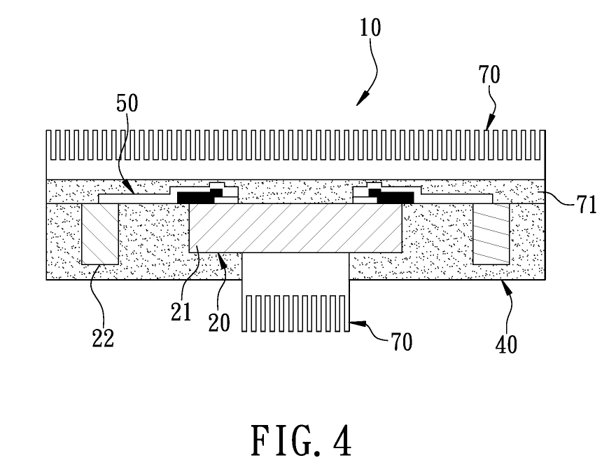

With reference to FIG. 4, another embodiment of an electronic element packaging is provided in this invention. The major structure is the same as that in the previous embodiment, so unnecessary details are not given here, in which a heat dissipation device 70 is provided on the unit 10 and may be arranged the chip 21 of the chipset 20 and then mounted with the colloid layer 40, or after the colloid layer 40 adhere and mount the chipset 20, the heat dissipation device 70 is mounted with the heat dissipation colloid 71 onto the unit 10 and sealed.

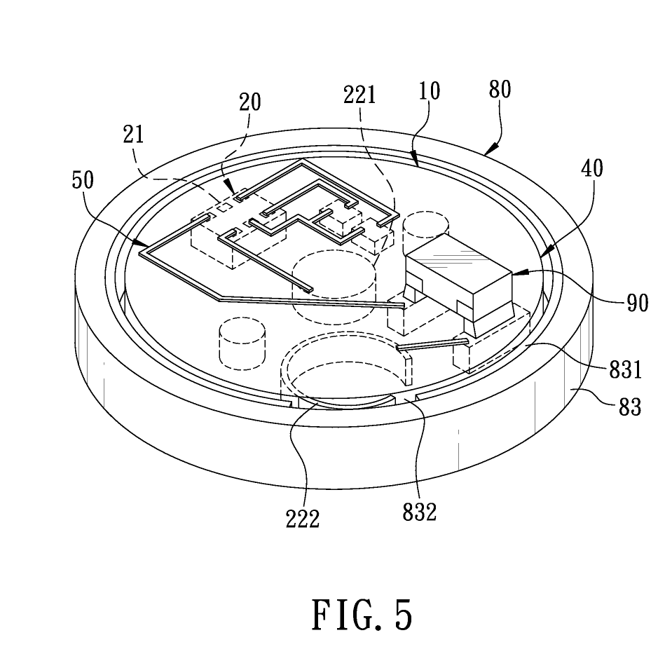

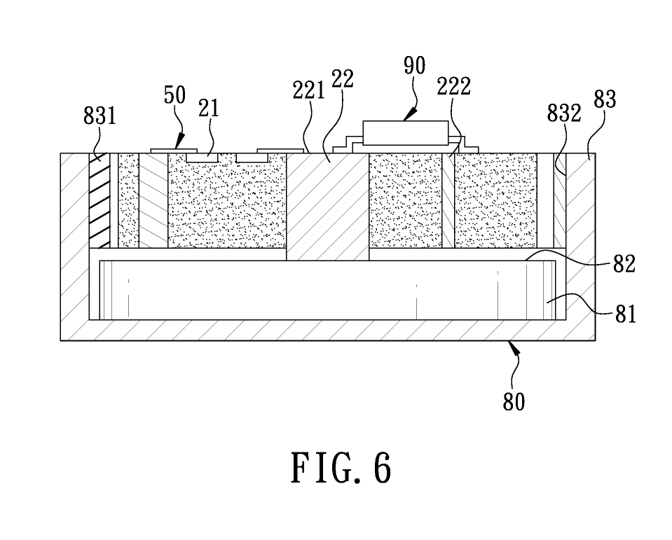

With reference to FIGS. 5 and 6, another embodiment of the electronic element packaging is provided in this invention, and the major structure is the same as that in the previous embodiment, so unnecessary details are not given here, in which the unit 10 is provided with a power supply unit 80 that serves as a cell 81 and the conductor 22 of the chipset 20 of the unit 10 is divided into a first conductor 221 and a second conductor 222 that are respectively connected to a first contact 82 and a second contact 83 that are provided in the power supply unit 80, in which a difference of voltage of the first contact 82 from the second contact 83 is generated. When the first conductor 221 and the second conductor 222 are respectively connected to the first contact 82 and the second contact 83, they are electrically conductive to generate current. The unit 10 is round. The first conductor 221 is provided in the center of a circle of the unit 10 and connected to the first contact 82 of the power supply unit 80. The second conductor 222 is a spring flake that protrudes from and arranged at a side of the unit 10. Besides, the second contact 83 of the power supply unit 80 is formed with a circular ring accommodating the unit 10, and the second contact 83 forms an insulated portion 831 and a conductive portion 832 at a side within the circular ring. The unit 10 may revolve in the power supply unit 80 and is conductive when the conductive portion 832 of second conductor 222 is connected to that of second contact 83. Open circuit is formed when the insulated portion 831 of second conductor 222 is connected to that of second contact 83, and thus the unit 10 becomes a switch. Further, the unit 10 is connected to an external circuit unit 90 that may serve as a light-emitting element, a passive element, an integrated circuit and the like for electrical driving according to various required applications.

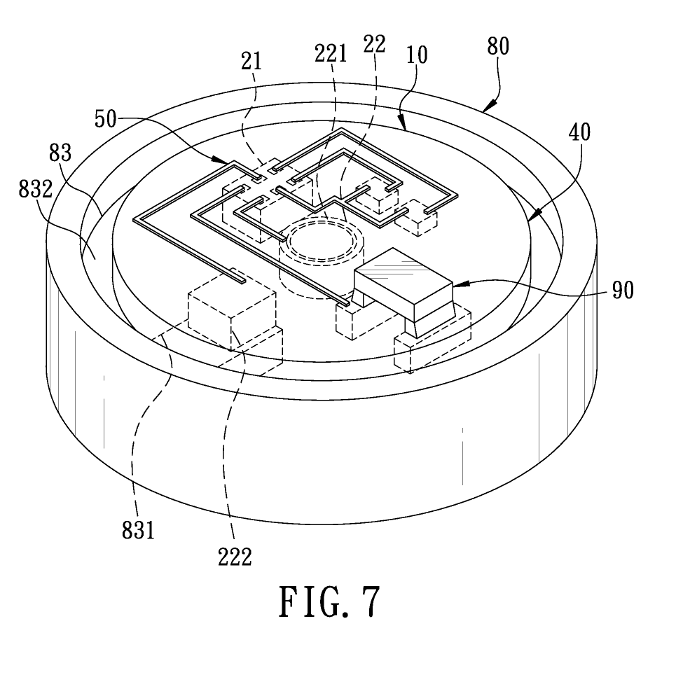

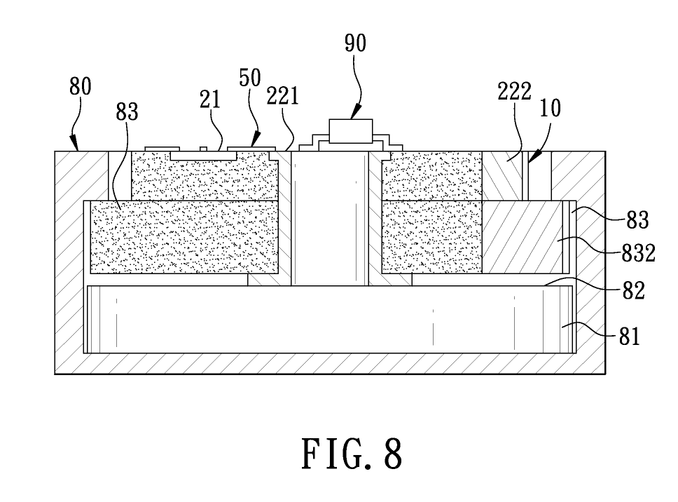

With reference to FIGS. 7 and 8, a next embodiment of the electronic element packaging is provided in this invention, and the major structure is the same as that in the previous embodiment, so unnecessary details are not given here, in which the unit 10 is piled onto the power supply unit 80; the first conductor 221 of the unit 10 is pivotally connected to the first contact 82 on the power supply unit 80; the unit 10 may pivot on the power supply unit 80 by using the first conductor 221; a bottom of the second conductor 222 of the unit 10 is connected a top face of the power supply unit 80; meanwhile, the top face of the power supply unit 80 is formed with the second contact 83 comprising the insulated portion 831 and the conductive portion 832; when the conductor 222 of the unit 10 is connected to the insulated portion 831 of the second contact 83, the circuit of unit is open; when the conductive portion 832 of the second conductor 222 is connected to that of the second contact 83, the unit 10 is conductive.

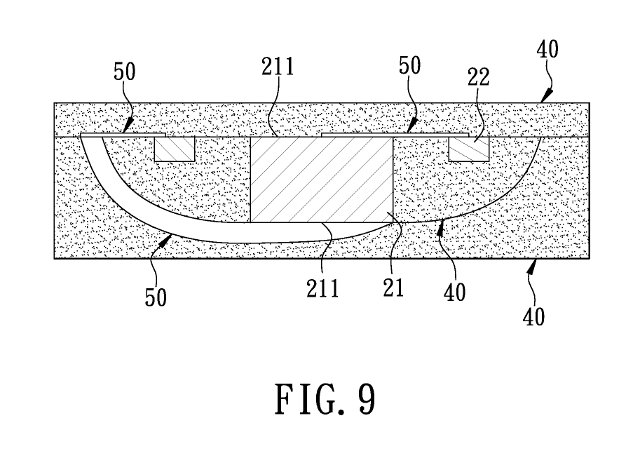

With reference to FIG. 9, a still next embodiment of the electronic element packaging is provided in this invention, and the major structure is the same as that in the previous embodiment, so unnecessary details are not given here, in which contacts 211 are provided at two bottom sides of the chip 21 of chipset 20, the colloid layer 40 is formed at only the bottom of the chip 21 for adhesion and mount, and after the contact 211 at the bottom of the chip 21 is connected to the top face by using the conductive portion 50, the second colloid layer 40 is adhered and mounted; besides, after the top face of the colloid layer 40 is connected to the conductor 22 and the chip 21 by using the conductive portion 50, a colloid layer 40 is adhered and mounted onto the top face.

Here, the features and attainable expected effects of this invention are described again below:

1. Regarding the electronic element packaging according to this invention, the chipset of the unit may be packaged without any substrate, which may reduce the costs of substrate use and design for the unit and thus may lower the possibility of damage caused by the thermal deformation for increasing its reliability and service life.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An electronic element packaging, the unit comprising at least:
a chipset provided with a conductor and a chip that are packaged without any substrate; and
a colloid layer making the chipsets to be adhered and mounted so that the chipset may mounted to the colloid layer.

2. The electronic element packaging according to claim 1, wherein the chip is a light-emitting component, an integrated circuit, or a passive component as an assembly.

3. The electronic element packaging according to claim 1, wherein a functional glue is provided around the chipset.

4. The electronic element according to claim 3 packaging, wherein the functional glue is a fluorescent colloid.

5. The electronic element packaging according to claim 1, wherein an active layer is formed at the outside of the unit.

6. The electronic element packaging according to claim 5, wherein the active layer is a diffusion film.

7. The electronic element packaging according to claim 5, wherein the active layer is a reflecting film.

8. The electronic element packaging according to claim 1, wherein a heat dissipation device is provided on the unit.

9. The electronic element packaging according to claim 1, wherein a conductive portion is provided between the chip and the conductor.

10. The electronic element packaging according to claim 9, wherein the conductive portion is a conductive glue.

11. The electronic element packaging according to claim 9, wherein the conductive portion is formed with a bonding wire.

12. The electronic element packaging according to claim 1, wherein the conductor is mounted to the chip.

13. The electronic element packaging according to claim 1, wherein a circuit unit is provided at the outside of the unit.

14. The electronic element packaging according to claim 1, wherein the chip is a light-emitting element, an integrated circuit, or a switch as an electronic element.

15. The electronic element packaging according to claim 1, wherein the conductor pf chipset of the unit is provided with at least a first conductor and a second conductor and a power supply unit is provided between the first conductor and the second conductor.

16. The electronic element packaging according to claim 15, wherein the power supply unit comprises a cell provided with a first contact and a second contact, a voltage difference is generated between the first contact and the second contact, and the first conductor is connected to the first contact and the second conductor is connected to the second contact.

17. The electronic element packaging according to claim 16, wherein the unit is round, the second contact is a ring, the unit is provided in the second contact, an insulated portion and a conductive portion is provided around the inside of the second contact, and the second conductor is connected to the inner annulus of the second contact.

18. The electronic element packaging according to claim 17, wherein the second conductor is a spring flake.

19. The electronic element packaging according to claim 16, wherein the unit is piled onto the power supply unit, the first conductor of the unit is pivoted to the power supply unit and connected to the first contact, the second unit is provide at a top of the power supply unit and provided with an insulated portion and a conductive portion, and the second conductor of the unit is provided at the bottom and connected to the second unit.
